(19) United States
(12) Patent Application Publication
(10) Pub. No.: US 2017/0278879 A1
(43) Pub. Date: Sep. 28, 2017

(54) METHOD FOR MANUFACTURING METAL LAMINATION FILM, METHOD FOR MANUFACTURING SEMICONDUCTOR DEVICE, AND METHOD FOR MANUFACTURING LIQUID CRYSTAL DISPLAY DEVICE

(71) Applicant: Sharp Kabushiki Kaisha, Osaka (JP)

(72) Inventors: Yoshinori HARADA, Osaka (JP); Yohhei SHINZAKI, Osaka (JP); Masaru SUGATA, Osaka (JP); Kenichi NISHIMURA, Osaka (JP)

(73) Assignee: Sharp Kabushiki Kaisha, Osaka (JP)

(21) Appl. No.: 15/506,904

(22) PCT Filed: Aug. 27, 2015
(86) PCT No.: PCT/JP2015/074136

§ 371 Date: Feb. 27, 2017

(30) Foreign Application Priority Data
Sep. 3, 2014 (JP) 2014-179195

(51) Int. Cl. H01L 27/12; H01L 29/786; G02F 1/1368

(52) U.S. Cl. CPC H01L 27/1296; G02F 1/1368; H01L 27/1222; H01L 29/78669; H01L 27/1225; H01L 29/78693; H01L 27/124

(57) ABSTRACT

The present invention includes: a multilayer film forming step of forming a multilayer film constituted by a plurality of metal films layered together; after the multilayer film forming step, a resist forming step of forming a resist film having patterned openings on the multilayer film; after the resist forming step, a dry etching step of dry etching the multilayer film to remove at least one metal film located at the top of the multilayer film and exposed by the openings; after the dry etching step, a wet etching step of wet etching the multilayer film to remove at least the metal films exposed by the openings.

### TECHNICAL FIELD

The technology described in the present specification relates to a method of manufacturing a metal multilayer film, a method of manufacturing a semiconductor device, and a method of manufacturing a liquid crystal display device.

### BACKGROUND ART

In the manufacturing process of a liquid crystal panel, which is a primary component of a liquid crystal display device, TFTs (thin film transistors) are disposed in a matrix pattern as switching devices on the array substrate forming a portion of the liquid crystal panel. The wiring lines constituting the various electrodes of the TFTs are sometimes metal multilayer films made of a plurality of metal films such as titanium, aluminum, etc. being layered together. This type of metal multilayer film is ordinarily formed by forming a resist film with patterned holes on the multilayer film constituted by the layered metal films and then dry etching the portions of the metal films exposed in the holes while using the resist film as the mask.

However, when forming the metal multilayer film by dry etching in this manner, etching dust from the etching sometimes attaches to the multilayer film. If etching dust attaches to the multilayer film, then etching defects such as the portion that the dust attached to not being etched may occur, which may lower the yield of the intended product. As a countermeasure, Patent Document 1 below discloses a method of manufacturing a liquid crystal display device whereby dry etching is not used, but rather the multilayer film is wet etched to form the metal multilayer film.

### RELATED ART DOCUMENT

### Patent Document

Patent Document 1: Japanese Patent Application Laid-Open Publication No. 2011-151194

### Problems to be Solved by the Invention

In recent years, however, the miniaturization of portable electronics such as smartphones and tablets has been followed by demand for higher resolutions of liquid crystal display devices. Nevertheless, if the metal multilayer film is formed by wet etching the multilayer film as in the method of manufacturing the liquid crystal display device described in Patent Document 1, there are large variations in etching amount and etching shift amount, which makes it difficult to form the metal multilayer film with high precision.

### SUMMARY OF THE INVENTION

The technology described in the present specification was made in view of the above problem and aims at manufacturing a metal multilayer film and semiconductor device with high yield and precision. The technology disclosed in the present specification further aims at manufacturing a high-resolution liquid crystal display device with high yield.

### Means for Solving the Problems

A technique described in the present specification relates to a method of manufacturing multilayer metal film, including: a multilayer film forming step of forming a multilayer film including a plurality of metal films layered together; after the multilayer film forming step, a resist forming step of forming a resist film that has openings patterned on the multilayer film; after the resist forming step, a dry etching step of dry etching the multilayer film to remove at least one of the metal films positioned at a top of the multilayer film in areas exposed by the openings; and after the dry etching step, a wet etching step of wet etching the multilayer film to remove at least the metal film remaining in the areas exposed by the openings.

According to the method of manufacturing the metal multilayer film described above, only the portion of the metal film located at the top of the multilayer film is removed by the dry etching step, and thus etching defects caused by metal film damage due to excessive etching or etching dust are more inhibited than if all layers of the multilayer film were to be dry etched. Thus, even if etching defects caused by etching dust were to occur, the magnitude would be insignificant, and the sections with etching defects could be removed during the wet etching step. This makes it possible to manufacture the metal multilayer film with a high yield.

Furthermore, in the dry etching step, a portion of the metal film located in the top layer of the multilayer film is removed, and thus the multilayer film can be wet etched while inhibiting infiltration of the etchant during the wet etching step, or namely without being affected by the oxide film formed on the surface of the multilayer film. When the wet etching step is being performed, the metal film at the top of the multilayer film has already been removed in the dry etching step, and thus it is possible to more easily control the etching shift amount than if wet etching were performed while the top layer of the multilayer film remains. This makes it possible to manufacture the metal multilayer film with high precision. As described above, the manufacturing method makes it possible to manufacture a metal multilayer film and semiconductor device with high yield and precision.

In the method of manufacturing the multilayer metal film, the multilayer film forming step may include forming the metal film containing titanium at a top of the multilayer film.

Titanium has high adhesiveness to silicon. According to the method of manufacturing described above, the metal layer located in the topmost layer of the multilayer film contains titanium, and thus when forming an insulating film or the like containing silicon on the metal multilayer film after manufacture of the metal multilayer film, it is possible to ensure a high adhesiveness between the insulating film or the like and the metal multilayer film, and possible to provide the insulating film with excellent coverage characteristics.

In the method of manufacturing the multilayer metal film, the multilayer film forming step may include forming the metal film containing titanium at a bottom of the multilayer film.

According to the method of manufacturing described above, the metal layer located in the bottommost layer of the multilayer film contains titanium, and thus when the base layer for forming the multilayer film contains silicon it is possible to ensure a high adhesiveness between the base layer and the metal insulating film, and possible to provide the base layer with excellent coverage characteristics.

In the method of manufacturing the multilayer metal film, an etching solution containing fluorine may be used in the wet etching step.

With this method of manufacturing, it is possible to improve the etching rate during the wet etching step when the metal film removed by the wet etching step contains titanium or the like.

The method of manufacturing the multilayer metal film may further include, between the dry etching step and the wet etching step, a cleaning step of cleaning the metal multilayer film using a cleaning solution.

With this method of manufacturing, during the cleaning step it is possible to effectively remove impurities remaining on the surface of the multilayer film after the dry etching step. This makes it possible to inhibit the occurrence of excess metal film residuals caused by remaining impurities and metal film damage, thus allowing for an even higher yield.

In the method of manufacturing the multilayer metal film, in the cleaning step, cleaning parameters may be set such that the cleaning solution is injected generally uniformly on the multilayer film.

With this method of manufacturing, in the cleaning step it is possible to even more effectively remove impurities remaining on the surface of the multilayer film after the dry etching step. This makes it possible to realize an even higher yield.

In the method of manufacturing the multilayer metal film, in the wet etching step, spraying parameters of an etching solution may be set such that the etching solution is sprayed generally uniformly in the areas exposed by the openings in the multilayer film.

With this method of manufacturing, it is possible to effectively remove etching dust from the dry etching step with the wet etching step. As a result, it is possible to further inhibit etching defects caused by etching dust and to achieve a higher yield.

Another technique described in the present specification relates to a method of manufacturing a semiconductor device, including: a semiconductor film forming step of forming a semiconductor film; and a multilayer metal film forming step of using the method of manufacturing the multilayer metal film to form a pair of the metal multilayer films, the pair of the metal multilayer films being electrically connected via the semiconductor film.

With this method of manufacturing, it is possible to form a pair of metal multilayer films with high precision and at a high yield, which thus makes it possible to manufacture a high-precision semiconductor device while realizing a high yield.

Another technique described in the present specification relates to a method of manufacturing a liquid crystal display device, including: a first substrate forming step of using the method of manufacturing the semiconductor device to form a plurality of the semiconductor devices in a matrix pattern on the first substrate; a second substrate forming step of forming a second substrate facing the first substrate; and a liquid crystal layer forming step of forming a liquid crystal layer containing liquid crystal molecules between the first substrate and the second substrate.

With this method of manufacturing, it is possible form a plurality of high-precision semiconductor devices corresponding to each pixel in the liquid crystal display device at a high yield; therefore, it is possible to manufacture a high-definition liquid crystal display device while realizing a high yield.

### Effects of the Invention

The technology described in the present specification makes it possible to manufacture a metal multilayer film and semiconductor device with high yield and precision. The technology disclosed in the present specification further makes it possible to manufacture a high-resolution liquid crystal display device with high yield.

### BRIEF DESCRIPTION OF THE DRAWINGS

FIG. 1 is a schematic cross-sectional view of a liquid crystal display device along the lengthwise direction.

FIG. 2 is a schematic plan view of the liquid crystal panel.

FIG. 3 is a schematic cross-sectional view showing a cross-sectional configuration of the liquid crystal panel.

FIG. 4 is a plan view of a planar configuration of a display area in an array substrate that forms a portion of the liquid crystal panel.

FIG. 5 is a cross-sectional view of a TFT shown in the V-V cross section in FIG. 4.

FIG. 6 is a cross-sectional view showing a manufacturing step (1) of the TFT.

FIG. 7 is a cross-sectional view showing a manufacturing step (2) of the TFT.

FIG. 8 is a cross-sectional view showing a manufacturing step (3) of the TFT.

FIG. 9 is a cross-sectional view showing a manufacturing step (4) of the TFT.

FIG. 10 is a cross-sectional view showing a manufacturing step (5) of the TFT.

FIG. 11 is a graph comparing residual film amount and disconnection defect amount between a source electrode manufactured by a conventional manufacturing method and a source electrode manufactured by a manufacturing method of Embodiment 1.

FIG. 12 is a graph comparing residual film amount and disconnection defect amount between a source electrode manufactured by a conventional manufacturing method and a source electrode manufactured by a manufacturing method of Embodiment 2.

FIG. 13 is a graph comparing residual film amount and disconnection defect amount between a source electrode manufactured by a conventional manufacturing method and a source electrode manufactured by a manufacturing method of Embodiment 3.

### DETAILED DESCRIPTION OF EMBODIMENTS

### Embodiment 1

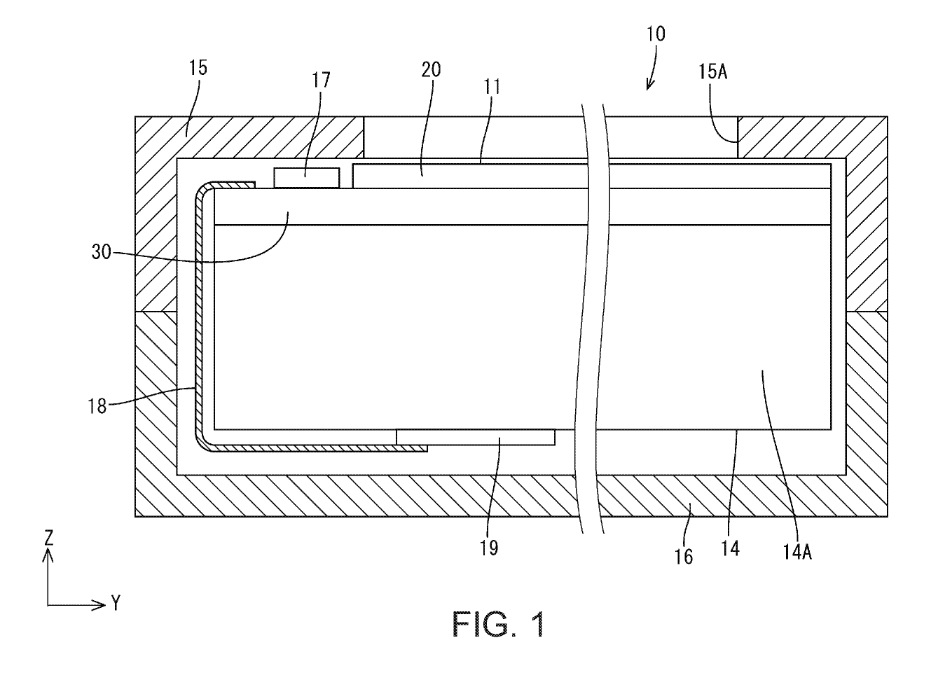

Embodiment 1 will be explained with reference to FIGS. 1 to 11. In the present embodiment, a liquid crystal display device 10 including a liquid crystal panel 11 will be described as an example. Each of the drawings indicates an X-axis, a Y-axis, and a-Z axis in a portion of FIGS. 1 to 10, and each of the axes indicates the same direction for the respective drawings. In FIGS. 1, 3, and 5-10, the top of the drawing is the top side (front side) of the liquid crystal display device 10.

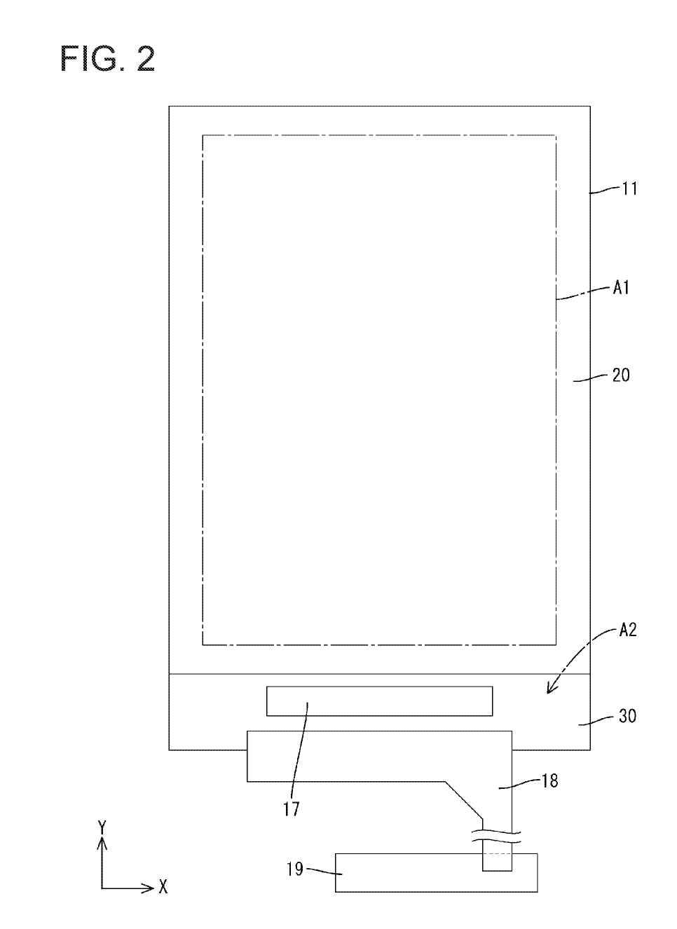

As shown in FIGS. 1 and 2, the liquid crystal display device 10 includes the liquid crystal panel 11, an IC chip 17, which is an electronic component that is mounted on and drives the liquid crystal panel 11, a controller substrate 19 that externally supplies various types of input signals to the IC chip 17, a flexible substrate 18 that electrically connects the liquid crystal panel 11 and the external controller substrate 19, and a backlight device 14, which is an external light source that supplies light to the liquid crystal panel 11. Furthermore, the liquid crystal display device 10 includes front and rear external members 15 and 16 for housing and holding the liquid crystal panel 11 and the backlight device 14, which are attached together, and the front external member 15 has an opening 15A that allows an image displayed on the liquid crystal panel 11 to be viewed from outside. The liquid crystal display device 10 of the present embodiment is used in smartphones and the like, and the liquid crystal panel 11 that forms a portion of the liquid crystal display device has a size of approximately 5 inches and a FHD (Full High Definition) resolution.

First, the backlight device 14 will be briefly explained. As shown in FIG. 1, the backlight device 14 includes a generally box-shaped chassis 14A that opens towards the front, a light source (cold cathode fluorescent tube, LED, organic EL, etc.; not shown) disposed inside the chassis 14A, and an optical member (not shown) disposed so as to cover the opening in the chassis 14A. The optical member has functions such as converting light emitted from the light source into planar light. The light that has passed through the optical member to become planar light enters the liquid crystal panel 11 and is used to display an image on the liquid crystal panel 11.

Next, the liquid crystal panel 11 will be described. As shown in FIG. 2, the liquid crystal panel 11 has a vertically-long rectangular shape as a whole, the lengthwise direction of which matches the Y-axis direction in each drawing and the widthwise direction matching the X-axis direction in each drawing. A large portion of the liquid crystal panel 11 is a display area A1 where images can be displayed, and the location on the panel towards one edge thereof in the lengthwise direction (the bottom in FIG. 2) is a non-display area A2 where images are not displayed. The IC chip 17 and flexible substrate 18 are mounted on a portion of the non-display area A2. As shown in FIG. 1, in the liquid crystal panel 11, the frame-shaped dot-dash line that is slightly smaller than the color filter substrate 20 (described later) forms the external shape of the display area A1, and the area outside this dot-dash line is the non-display area A2.

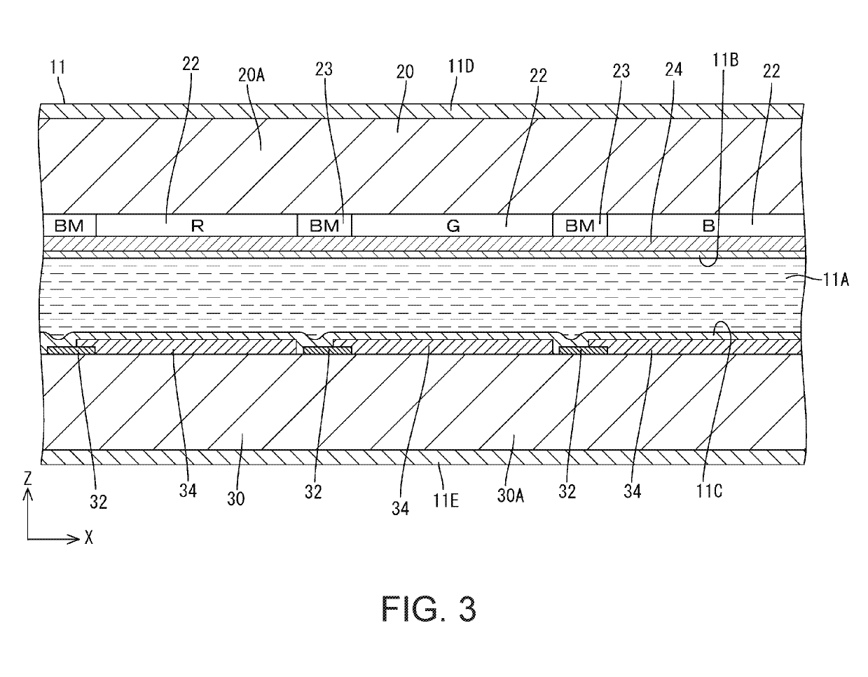

As shown in FIG. 3, the liquid crystal panel 11 includes a pair of glass substrates 20 and 30 with excellent transmissive characteristics, and a liquid crystal layer 11A having liquid crystal molecules, which are a material whose optical characteristics change in accordance with the electrical field applied thereto. Both substrates 20 and 30 constituting the liquid crystal panel 11 are bonded together by a sealant (not shown) in a state in which a cell gap equivalent to the thickness of the liquid crystal layer 11A is maintained between the substrates. Among both substrates 20 and 30, the front side (upper side) substrate 20 is the color filter substrate (one example of a second substrate) 20, and the rear side (back side) substrate 30 is the array substrate (one example of a first substrate) 30. Alignment films 11B and 11C for aligning the liquid crystal molecules included in the liquid crystal layer 11A are respectively formed on the inner surface sides of the two substrate 20 and 30. Polarizing plates 11D and 11E are respectively affixed to the outer surface sides of the glass substrates 20A and 30A constituting both substrates 20 and 30.

As shown in FIG. 2, among both substrates 11A and 11B, the color filter substrate 20 has approximately the same widthwise dimensions as the array substrate 30, whereas the lengthwise dimensions are smaller than the array substrate 11B, and the substrates are bonded together with one end of the array substrate 30 in the lengthwise direction (the top in FIG. 2) coinciding in position with the color filter substrate. Accordingly, the other end of the array substrate 30 in the lengthwise direction (the bottom in FIG. 2) does not overlap the color filter substrate 20 over a prescribed range, with both front and rear surfaces being exposed to outside, and this exposed area is secured as the mounting area of the IC chip 17 and flexible substrate 18. The glass substrate 30A constituting the array substrate 30 has the color filter substrate 20 and polarizing plate 11E bonded to the primary section thereof, and the section secured for the mounting area of the IC chip 17 and flexible substrate 18 does not overlap the color filter substrate 20 and polarizing plate 11E.

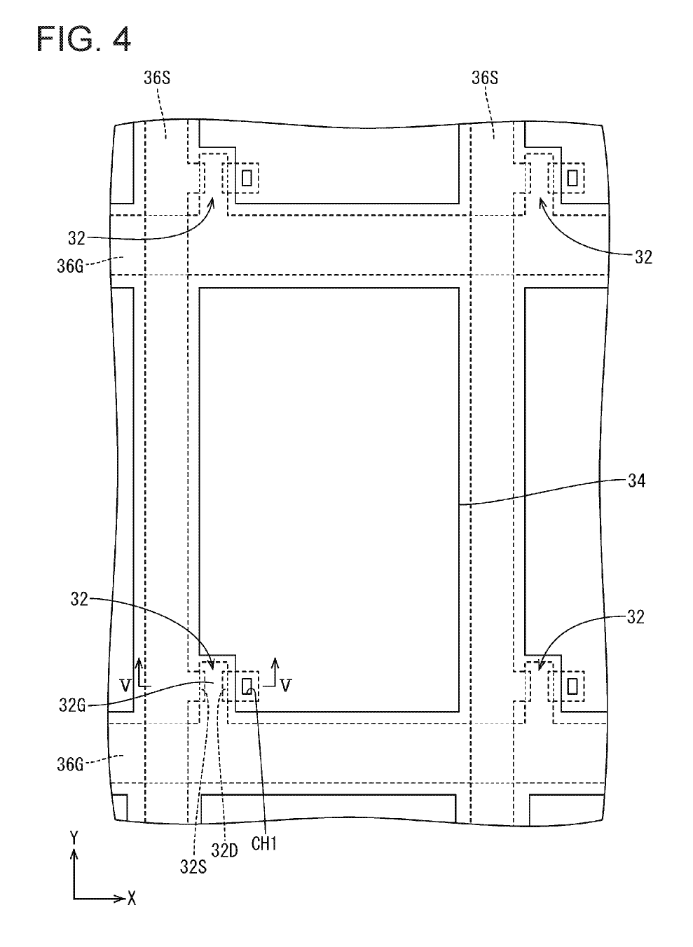

Next, the configuration inside the display area A1 of the array substrate 30 and color filter substrate 20 will be described. As shown in FIGS. 3 and 4, a large number of TFTs (one example of a semiconductor device) 32, which are switching devices each having three electrodes 32G, 32S, 32D, and pixel electrodes 34 (described later) made of a transparent conductive film such as ITO (indium tin oxide) and connected to the drain electrodes 32D of the TFTs 32 are provided in a matrix pattern on the inner surface side (liquid crystal layer 11A side) of the glass substrate 30A constituting the array substrate 30. As shown in FIG. 4, gate wiring lines 36G and source wiring lines (one example of a metal multilayer film) 36S are arranged in a grid-like pattern so as to surround these TFTs 32 and pixel electrodes 34. The gate wiring lines 36G extend in the X-axis direction, whereas the source wiring lines 36S extend in the Y-axis direction, and the wiring lines 36G and 36S intersect with one another. As shown in FIG. 4, the pixel electrode 34 has a vertically-long rectangular shape in a plan view of the region surrounded by the gate wiring lines 36G and source wiring lines 36S. The pixel size (X-axis direction dimensions) of the pixel electrode 34 is approximately 20 μm.

The array substrate 30 is provided with capacitance wiring lines (not shown) that are parallel to the gate wiring lines 36G and overlap the pixel electrodes 34 in a plan view. The capacitance wiring lines are arranged alternately with the gate wiring lines 36G in the Y-axis direction. The gate wiring lines 36G are each disposed between pixel electrodes 34 adjacent in the Y-axis direction, whereas the capacitance wiring lines are disposed across approximately the center of each pixel electrode 34 in the Y-axis direction. Terminals led out from the gate wiring lines 36G and capacitance wiring lines, and terminals led out from the source wiring lines 36S are provided on the end of the array substrate 30. These terminals respectively receive a signal or reference potential from the controller substrate 19 shown in FIG. 1, which controls driving of the TFTs 32.

Meanwhile, as shown in FIG. 3, a large number of color filters 22 arranged next to one another in a matrix pattern are provided on the inner surface side (liquid crystal layer 11A) side of the glass substrate 20A constituting the color filter substrate 20 so as to overlap the respective pixel electrodes 34 on the array substrate 30 side in a plan view. These color filters 22 are constituted by respective colored portions such as R (red), G (green), and B (blue). A light-shielding part (black matrix) 23 is formed in a generally grid-like pattern between the respective colored portions constituting the colored filters 22 in order to prevent colors mixing. The light-shielding part 23 is positioned overlapping the gate wiring lines 36G, source wiring lines 36S, and capacitance wiring lines on the array substrate 30 in a plan view. In the liquid crystal panel 11, one display pixel, which is a display unit of the liquid crystal panel 11, is formed of a group of three colored portions R (red), G (green), and B (blue), and three pixel electrodes 34 opposing these portions. A display pixel is made of a red pixel having an R colored portion, a green pixel having a G colored portion, and a blue pixel having a B colored portion. These respective pixels are repeatedly arranged next to one another along the row direction (X-axis direction) on the surface of the liquid crystal panel 11 to form a pixel group, and a large number of these pixel groups are arranged next to each other along the column direction (Y-axis direction).

As shown in FIG. 3, the inner surface sides of the color filters 22 and light-shielding portion 23 are provided with an opposite electrode 24 facing the pixel electrodes 34 on the array substrate 30 side. An opposite electrode wiring line (not shown) is disposed in the non-display area A2 of the liquid crystal panel 11, and this opposite electrode wiring line is connected to the opposite electrode 24 via a contact hole (not shown). A reference potential is applied to the opposite electrode 24 from the opposite electrode wiring line, and the TFT 32 controlling the potential applied to the pixel electrode 34 makes it possible to generate a prescribed difference in potential between the pixel electrode 34 and opposite electrode 24.

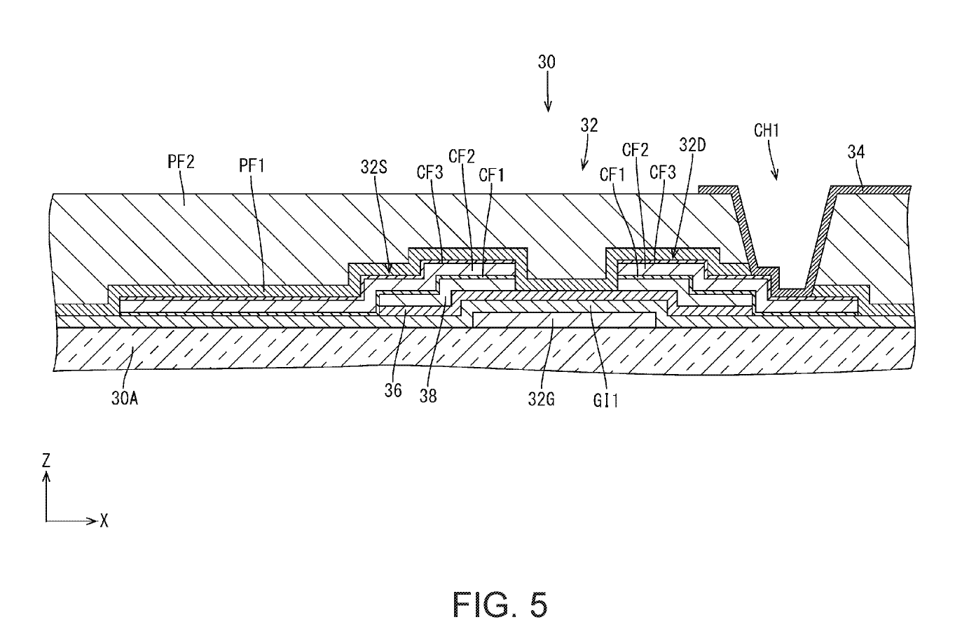

Next, the TFTs 32, which are switching devices provided on the array substrate 30, will be described in detail. As shown in FIGS. 4 and 5, the TFT 32 is formed in a layer above the gate wiring line 36G. The gate wiring line 36G branches from the vicinity of the intersection with the source wiring line 36S and extends in parallel to the source wiring line 36S. The source wiring line 36S also branches from the vicinity of the intersection with the gate wiring line 36G and extends in parallel to the gate wiring line 36G. The tip of the gate electrode 36G that has branched and extended overlaps in a plan view with the tip of the source wiring line 36S that has branched and extended, and the TFT 32 is provided in this overlapping area. The area of the gate wiring line 36G overlapping the TFT 32 in a plan view constitutes the gate electrode 32G of the TFT 32, and the area of the source wiring line 36S overlapping the gate electrode 32G in a plan view constitutes the source electrode 32S of the TFT 32. Furthermore, the TFT 32 has an island-shaped drain electrode 32D facing the source electrode 32S with a prescribed gap in the X-axis direction therebetween. The source electrode 32S and drain electrode 32D are made of the same material as the source wiring line 36S and patterned on the array substrate 30 in the same step as the source wiring line 36S.

In the TFT 32, a semiconductor film 36 is formed above the gate electrode 32G so as to bridge the gap between the source electrode 32S and drain electrode 32D. On the semiconductor film 36, contact films 38 are respectively formed between the semiconductor film and the source electrode 32S and between the semiconductor film and the drain electrode 32D. The contact film 38 functions to create an Ohmic contact between the semiconductor film 36 and the source electrode 32S and between the semiconductor film 36 and the drain electrode 32D. In this example, the source electrode 32B and drain electrode 32D are arranged facing each other with a prescribed gap (aperture region) therebetween, and thus the source and drain are not directly electrically connected to each other. However, the source electrode 32B and drain electrode 32D are indirectly electrically connected via the semiconductor layer 36 below, and the bridge portion of the semiconductor film 36 between these electrodes 32B and 32C functions as a channel region where drain current flows.

Next, the various insulating films layered on the array substrate 30 will be described with reference to FIG. 5. In order from the bottom (the glass substrate 30A side), the insulating films layered on the array substrate 30 are a gate insulating film GI1, first protective film PF1, and second protective film PF2. The gate insulating film GI1 is layered at least above the gate wiring line 36G and gate electrode 32G and is made of a transparent inorganic material. The first protective film PF1 is disposed above at least the source electrode 32S and drain electrode 32D and is made of a transparent inorganic material. The second protective film PF2 is disposed above the first protective film PF1 and made of a transparent inorganic material. The location of the first protective film PF1 and second protective film PF2 overlapping a portion of the drain electrode 30D in a plan view has a contact hole CH1 vertically penetrating therethrough, and the drain electrode 32D is exposed within the contact hole CH1. The pixel electrode 34 is formed on an area above second protective film PF2 so as to straddle this contact hole CH1, and the pixel electrode 34 is connected to the drain electrode 32D through the contact hole CH1.

Next, the material constituting the various films formed in the TFTs 32 and the vicinity of the TFTs 32 will be explained. The gate wiring line 36G and gate electrode 32G are patterned on the array substrate 30 and are made of a metal multilayer film constituted by a plurality of metal films layered together. The metal multilayer film constituting the gate wiring line 36G and gate electrode 32G has a multilayer structure with tungsten (W) at a thickness of 300 nm and silicon nitride (SiNx) at a thickness of 325 nm, for example. The source wiring line 36S, source electrode 32S, and drain electrode 32D are made of the same material and are all multilayer films with a three-layer structure. The source wiring line 36S, source electrode 32S, and drain electrode 32D have a configuration in which, from the bottom, a first conductive film (one example of a metal film) CF1 made of titanium (Ti), a second conductive film (one example of a metal film) CF2 made of aluminum (Al), and a third conductive film (one example of a metal film) CF3 made of titanium are layered in this order. The first conductive film CF1 has a thickness of 20 to 50 nm, for example, the second conductive film CF2 has a thickness of 300 to 400 nm, for example, and the third conductive film CF3 has a thickness of 20 to 50 nm, for example.

The gate insulating film GI1 is made of a 50 nm silicon oxide film (SiOx), for example, and insulates the gate electrode 32G from the semiconductor film 36. The first protective film PF1 is made of a silicon oxide film (SiOx), for example, and is made of the same material as the gate insulating film GI1. The second protective film PF2 is made of an organic acrylic resin (e.g., polymethyl methacrylate (PMMA)) or polyimide resin. Accordingly, the second protective film PF2 is thicker than the inorganic gate insulating film GI1 and first protective film PF1 and functions as a planarizing film. Each of the insulating films in the TFT 32 (first gate insulating film GI1, first protective film PF1, second protective film PF2) are formed at a uniform thickness across generally the entire array substrate 30 including regions outside where the TFTs 32 are formed. The semiconductor film 36 is made of 50 nm-thick amorphous silicon (a-Si) or an amorphous oxide semiconductor (InGaZnOx), for example, and the semiconductor film has one end connecting to the drain electrode 32D and the other end connecting to the source electrode 32S to function as a channel to electrically connect the source and drain. The contact film 38 is made of amorphous silicon (n+Si) doped with a high concentration of an n-type impurity such as phosphorous (P).

The above is a configuration of the liquid crystal panel 11 of the present embodiment, and next an example of a method of manufacturing the liquid crystal panel 11 having a configuration similar to above will be described. Of the members constituting the liquid crystal panel 11, the method of manufacturing the array substrate 30 in particular will be described in detail below. A method of manufacturing the color filter substrate 20 will be described first. First, the thin-film light-shielding part 23 is deposited onto the glass substrate 20A and processed into a general grid-like pattern via photolithography. The light-shielding part 23 is made of titanium (Ti), for example, and has a thickness of 200 nm, for example. Next, the respective colored portions constituting the color filters 22 are formed in the desired locations. Next, a transparent insulating film is formed as the protective film so as to cover the light-shielding part 23 and color filters 22. This insulating film is made of silicon dioxide (SiO2), for example, and has a thickness of 200 nm, for example. Thereafter, the alignment film 11B is formed on the surface of the insulating film. The above process completes the color filter substrate 20. The process of manufacturing the color filter substrate 20 is one example of a second substrate forming step.

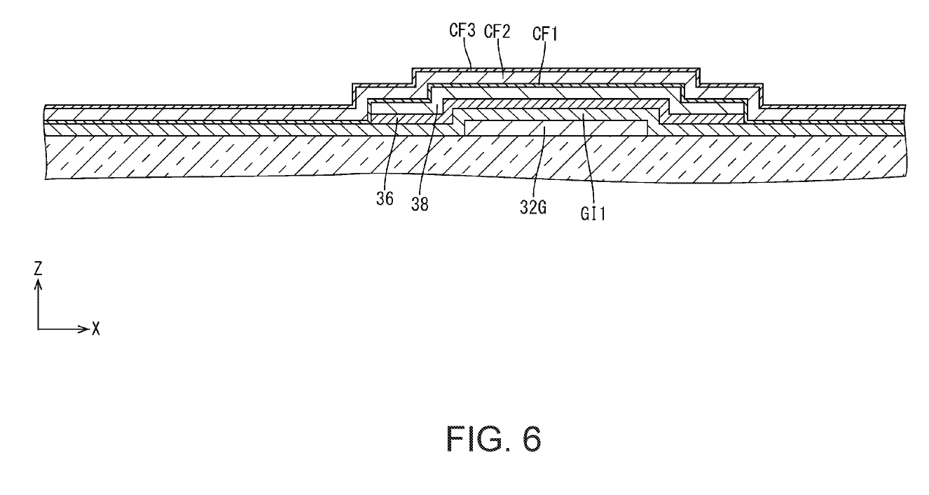

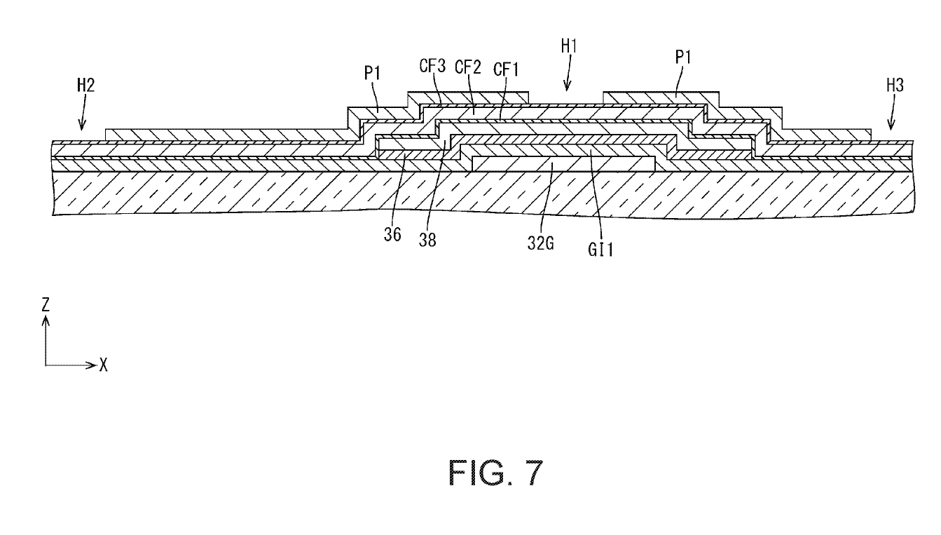

Next, a method of manufacturing the array substrate 30 will be explained. First, a metal film constituting the gate wiring line 36G and gate electrode 32G is formed on the glass substrate 30A and photolithography is used to process the film in the desired pattern. Next, the gate insulating film GI1 is formed and processed into the desired pattern via photolithography. Next, the semiconductor film 36 is formed on the gate insulating film GI1 and processed into the desired pattern via photolithography (one example of a semiconductor film forming step). Next, as shown in FIG. 6, the multilayer film constituting the source wiring line 36S, source electrode 32S, and drain electrode 32D (the films each constituted by the respective first conductive film CF1, second conductive film CF2, and third conductive film C3 being layered together) is formed (one example of a multilayer film forming step). Next, as shown in FIG. 7, a photoresist film P1 (one example of a resist film) having patterned openings H1, H2, and H3 is formed on the multilayer film (one example of a resist forming step).

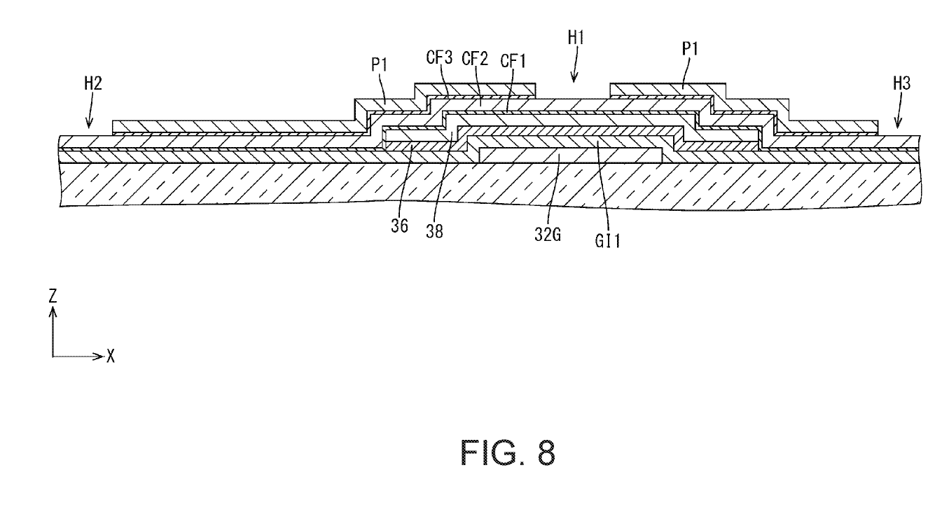

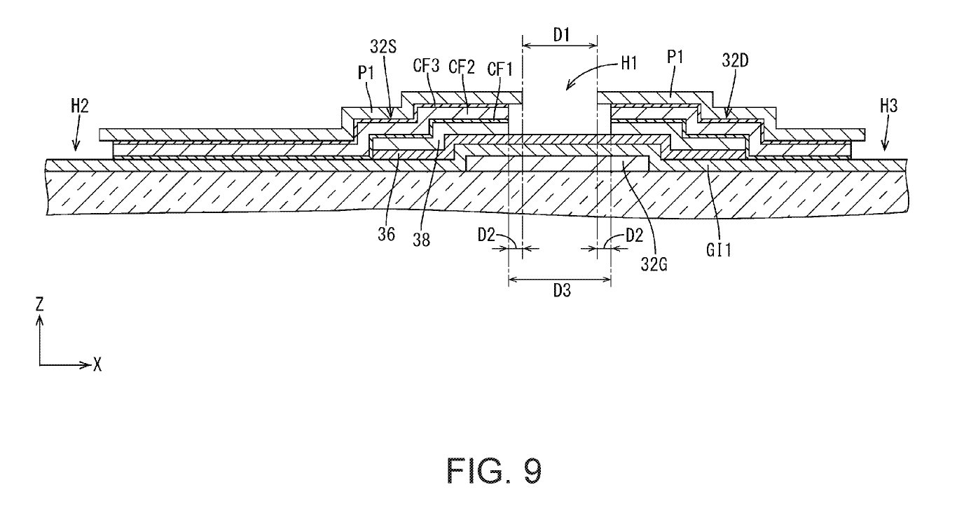

Next, as shown in FIG. 8, the multilayer film is dry etched to remove only the portion of the third conductive film CF3 located at the top of the multilayer film exposed by the openings H1, H2, and H3 in the photoresist film P1 (one example of a dry etching step). There are no limitations to the parameters for the dry etching in this step. Next, as shown in FIG. 9, the multilayer film is wet etched to remove the remaining portions of the second conductive film CF2 and first conductive film CF1 exposed by the openings H1, H2, and H3 in the photoresist film P1 (one example of a wet etching step). In this step, wet etching is performed by using a hydrofluoric acid etching solution containing a small amount of fluorine. Furthermore, in this step, the spray parameters of the etching solution are set such that the etching solution is generally uniformly sprayed in the portions of the multilayer film exposed by the openings H1, H2, and H3 in the photoresist film P1. This effectively removes etching dust and the like resulting from the dry etching.

However, because the wet etching is isotropic etching, wet etching the multilayer film also slightly etches the side faces of the second conductive film CF1 and first conductive film

CF1 below the opening edge in the photoresist film P1. The amount D2 (see FIG. 9) that the side faces of the second conductive film CF2 and first conductive film CF1 are etched in this step (hereinafter, “etching shift amount”) is around 0.56 μm for each. In conventional methods of manufacturing the source wiring lines, source electrodes, and drain electrodes by wet etching all of the layers of the multilayer film, the etching shift amount is around 0.84 μm, and thus the manufacturing method of the present embodiment can greatly reduce the etching shift amount during manufacturing of the source wiring lines 36S, source electrodes 32S, and drain electrodes 32D. As shown in FIG. 9, removing the second conductive film CF2 and first conductive film CF1 as described above forms the source electrode 32S and drain electrode 32D (one example of a metal multilayer film forming step) to form the TFT 32. In the manufacturing process of the array substrate of the present embodiment, the TFTs 32 are formed in a matrix pattern on the glass substrate 30A.

In this example, among the openings H1, H2, and H3 in the photoresist film P1, the width D1 (see FIG. 9) of the opening H1 located between the source electrode 32S and drain electrode 32D is approximately 2.6 μm. Accordingly, the width D3 (see FIG. 9) between the source electrode 32S and drain electrode 32D is approximately 3.72 μm, which is the etching shift amount of the source electrode 32S and the etching shift amount of the drain electrode 32D added to the width D2 of the opening H1. During forming of the source electrode 32S and drain electrode 32D, a photolithography device is used to expose the photoresist film P1 with g line and h line exposure, for example, but the limits for photolithography processing this photolithography device is normally 2.5 μm. In contrast, the width D1 of the opening H1 in the photoresist film P1 as described above is 2.6 μm, which makes it possible to ensure an allowable width of 0.1 μm. The source wiring line 36S, source electrode 32S, and drain electrode 32D formed by the method of manufacturing of the present embodiment has less etching cross-sectional roughness than the source wiring line, source electrode, and drain electrode of conventional manufacturing methods where all layers of the multilayer film are wet etched.

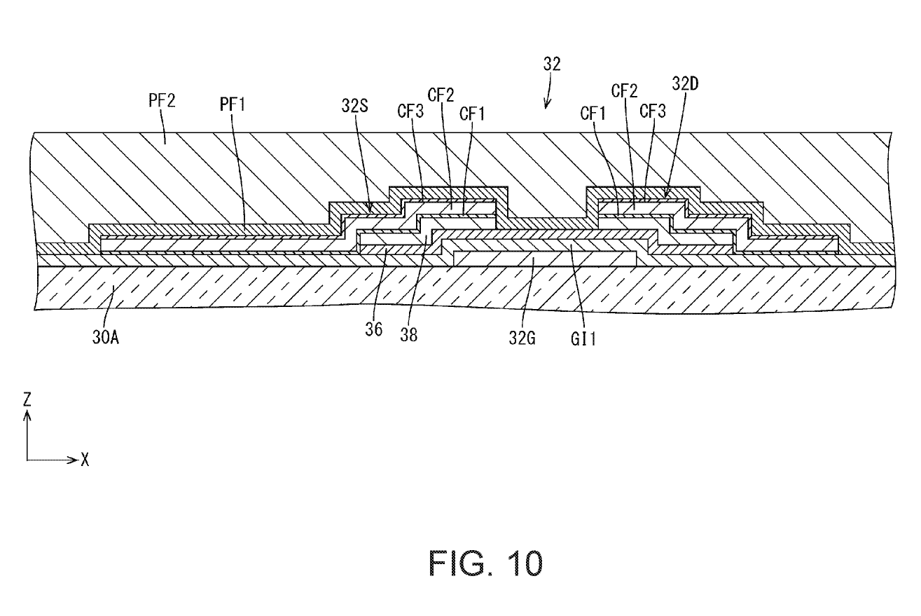

When the source electrode 32S and drain electrode 32D are formed, the photoresist film P1 is removed next by supplying a resist removal solution on the photoresist film P1. Next, as shown in FIG. 10, the first protective film PF1 and second protective film PF2 are formed in this order so as to cover the source electrode 32S and the drain electrode 32D. Next, exposing a portion of the drain electrode 32D forms the contact hole CH1 that penetrates through the first protective film PF1 and second protective film PF2, and the pixel electrode 34 is formed straddling the contact hole CH1. Thereafter, the alignment film 11C is formed on the surface of the pixel electrode 34. This alignment film 11C is an optical alignment film made of a polyimide, for example, and illuminating the alignment film with light of a specific wavelength range (ultraviolet, etc.) during the manufacturing process of the array substrate 30 makes it possible to align the liquid crystal molecules along the illumination direction of the light. The above process completes the array substrate 30. The process of forming the array substrate 30 is one example of a first substrate forming step.

Next, photospacers are arranged on the alignment film 11C of the array substrate 30 and both substrates 20 and 30 are bonded together with the alignment film 11C of the array substrate 30 and the alignment film 11B of the color filter substrate 20 facing inward, thus forming a bonded substrate. Next, liquid crystal is injected into the gap formed by the photospacers between the array substrate 30 and the color filter substrate 20, and a liquid crystal layer 11C is formed between both substrates 20 and 30 (one example of a liquid crystal layer forming step). Next, the bonded substrate is cut to the desired size. Thereafter, the polarizing plates 11D and 11E are respectively attached to the outer surface sides of the color filter substrate 20 and the array substrate 30, thereby completing the liquid crystal panel 11 of the present embodiment.

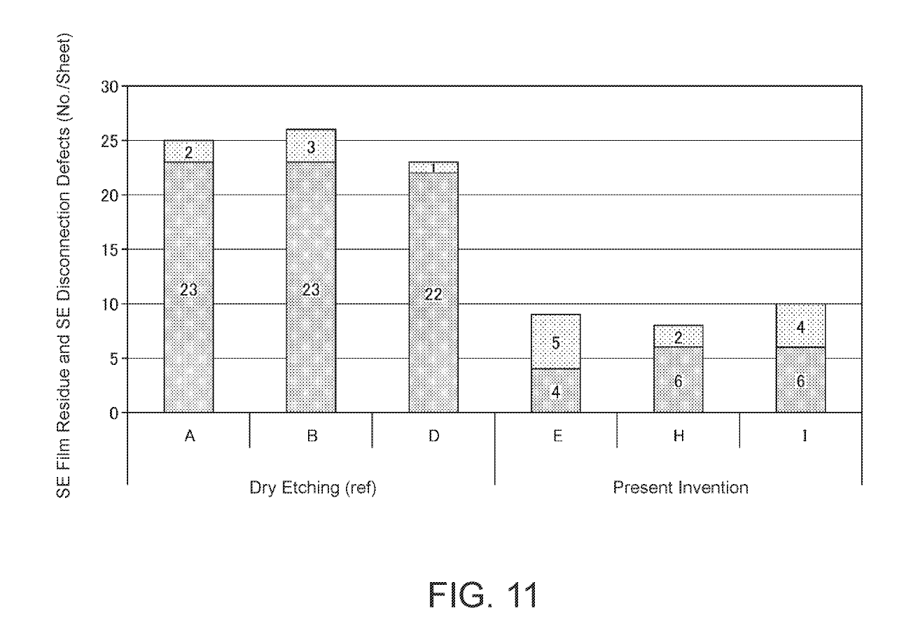

The graph in FIG. 11 shows comparisons between the number of source electrode disconnection defects due to film residual defects and excessive etching of the source electrode (SE) caused by improper etching for a source electrode formed by a conventional manufacturing method (hereinafter, “conventional method”) where all layers of the multilayer film are etched and the source electrode 32S formed by the manufacturing method of the present embodiment. The horizontal axis of the graph in FIG. 11 shows three samples (A, B, C) of a configuration (dry etching (ref)) formed by a conventional method and three samples (E, H, I) of a configuration (present invention) formed by a manufacturing method of the present embodiment. Furthermore, the vertical axis in FIG. 11 shows the number of film residual defects of the source electrode (the dark shaded portion on the graph) and the number of source electrode disconnection defects (the light shaded portion on the graph) that have occurred per one array substrate (one sheet). As shown by the graph in FIG. 11, while there is not a large difference between the number of source electrode disconnection defects in the configuration via the conventional method and the manufacturing method of the present embodiment, the number of film residual defects of the source electrode is significantly reduced in the configuration made by the manufacturing method of the present embodiment as compared to the configuration made by the conventional method. As a result, using the manufacturing method of the present embodiment significantly reduces the total number of film residual defects of the source electrode and disconnection defects of the source electrode (i.e., the number of defective products).

As described above, the method of manufacturing the source wiring line 36S, source electrode 32S, and drain electrode 32D of the present embodiment removes only the third conductive film CF3 located at the top of the multilayer film during the dry etching process, and thus etching defects caused by film damage due to excessive etching or etching dust are more inhibited than if all layers of the multilayer film were to be dry etched. Thus, even if etching defects caused by etching dust were to occur, the magnitude would be insignificant, and the sections with etching defects can be removed during the wet etching step. Thus, it is possible to manufacture the source wiring line 36S, source electrode 32S, and drain electrode 32D with a high yield.

Furthermore, during the dry etching process the third conductive film CF3 located in the top layer of the multilayer film is removed, and thus the multilayer film can be wet etched while inhibiting infiltration of the etchant during the wet etching process, or namely without being affected by the oxide film formed on the surface of the multilayer film. When wet etching is being performed, the third conductive film CF3 at the top of the multilayer film has already been removed in the dry etching process, and thus it is possible to more easily control the etching shift amount than if wet etching were performed while the top layer of the multilayer film remains. Thus, it is possible to manufacture the source wiring line 36S, source electrode 32S, and drain electrode 32D with high precision. When the size of a liquid crystal panel is 5 inches with a FHD resolution, the width of the gap between the source electrode and drain electrode is approximately 4.0 μm at the narrowest areas, for example. In contrast, the manufacturing method of the present embodiment can have a width D3 of approximately 3.72 μm for the gap between the source electrode 32S and drain electrode 32D as described above, and thus it is possible to realize a high-definition liquid crystal panel 11.

Furthermore, in the present embodiment, the titanium third conductive film CF3 is formed on the topmost layer of the multilayer film in the manufacturing process of the source wiring line 36S, source electrode 32S, and drain electrode 32D. Titanium has a high adhesiveness to silicon. In the manufacturing method of the present embodiment, the silicon first protective film PF1 is formed on the third conductive film CF3 after manufacture of the source wiring line 36S, source electrode 32S, and drain electrode 32D; therefore, it is possible to achieve a high adhesiveness between the third conductive film and the first protective film PF1, and as a result it is possible to provide the first protective film PF1 with excellent coverage characteristics.

Furthermore, in the present embodiment, the titanium first conductive film CF1 is formed on the bottommost layer of the multilayer film in the manufacturing process of the source wiring line 36S, source electrode 32S, and drain electrode 32D. In the manufacturing method of the present embodiment, the first conductive film CF1 is formed on the silicon gate insulating film GI1, and thus it is possible to achieve a high adhesiveness between the gate insulating film GI1 and the first conductive film CF1, and as a result it is possible to provide the gate insulating film GI1 with excellent coverage characteristics.

Furthermore, in the present embodiment, a fluorine etching solution is used during wet etching in the manufacturing process of the source wiring line 36S, source electrode 32S, and drain electrode 32D. The first conductive film CF1 removed by wet etching contains titanium. Thus, it is possible to improve the etching rate for when the first conductive film CF1 is removed by wet etching, which allows for effective wet etching.

Furthermore, in the present embodiment, during the wet etching step the spray parameters of the etching solution are set such that the etching solution is generally uniformly sprayed in the portions of the multilayer film exposed by the openings H1, H2, and H3 in the photoresist film P1. Therefore, it is possible to effectively remove etching dust from dry etching with the wet etching. As a result, it is possible to further inhibit etching defects caused by etching dust and to achieve a higher yield.

Moreover, the manufacturing method of the present embodiment makes it possible to realize a high yield while manufacturing high-precisions TFTs 32 by forming the source wiring line 36S, source electrode 32S, drain electrode 32D, and forming the semiconductor film 36 electrically connecting the source electrode 32S to the drain electrode 32D.

In addition, in the manufacturing method of the present embodiment, the array substrate 30 is formed by forming a plurality of the high-precision TFTs 32 in a matrix pattern while realizing a high yield as described above, and the color filter substrate 20 and liquid crystal layer 11A are each formed, thereby making it possible to manufacture the high-definition liquid crystal display device 10 while realizing a high yield.

### Embodiment 2

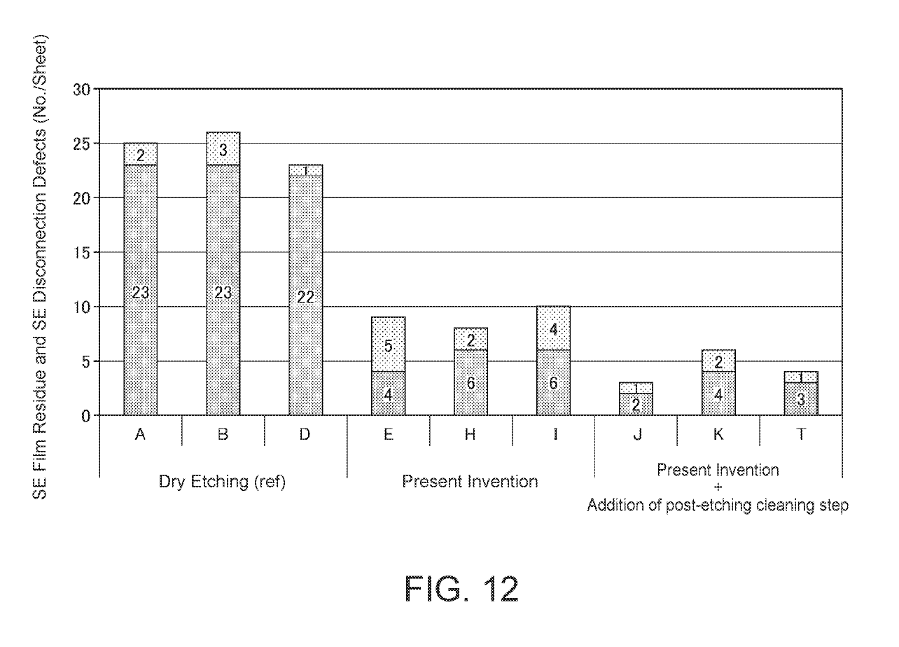

Embodiment 2 will be described with reference to FIG. 12. In Embodiment 2, in the process of manufacturing the source wiring line, source electrode, and drain electrode, the portion of the third conductive film exposed by the openings in the photoresist film are removed by dry etching, and thereafter a cleaning solution is sprayed on the surface of the source wiring line, source electrode, and drain electrode to clean the surface of the source wiring line, source electrode, and drain electrode (one example of a cleaning step). The graph in FIG. 12 shows comparisons between the number of source electrode disconnection defects due to film residual defects and excessive etching of the source electrode caused by improper etching for a source electrode formed by a conventional method, a source electrode formed by the manufacturing method of Embodiment 1 (hereinafter, “method of Embodiment 1”), and a source electrode formed by the manufacturing method of the present embodiment or namely a manufacturing method with the added cleaning step described above (hereinafter, “the present method”). The horizontal axis of FIG. 12 includes the items shown on the horizontal axis of FIG. 11 and additionally three samples (J, K, T) of the configuration formed by the present method (i.e., present invention+addition of post-etching cleaning). Furthermore, the items shown by the vertical axis in FIG. 12 are the same as the vertical axis in FIG. 11.

As shown by the graph in FIG. 11, the number of disconnection defects of the source electrode is smaller than in the method of Embodiment 1, and in addition the number of disconnection defects of the source electrode is also smaller than in the configuration of the conventional method and the configuration of the method of Embodiment 1. As a result, using the present method reduces the total number of film residual defects of the source electrode and disconnection defects of the source electrode (i.e., the number of defective products) as compared to the method of Embodiment 1. This makes it possible to realize an even higher yield.

### Embodiment 3

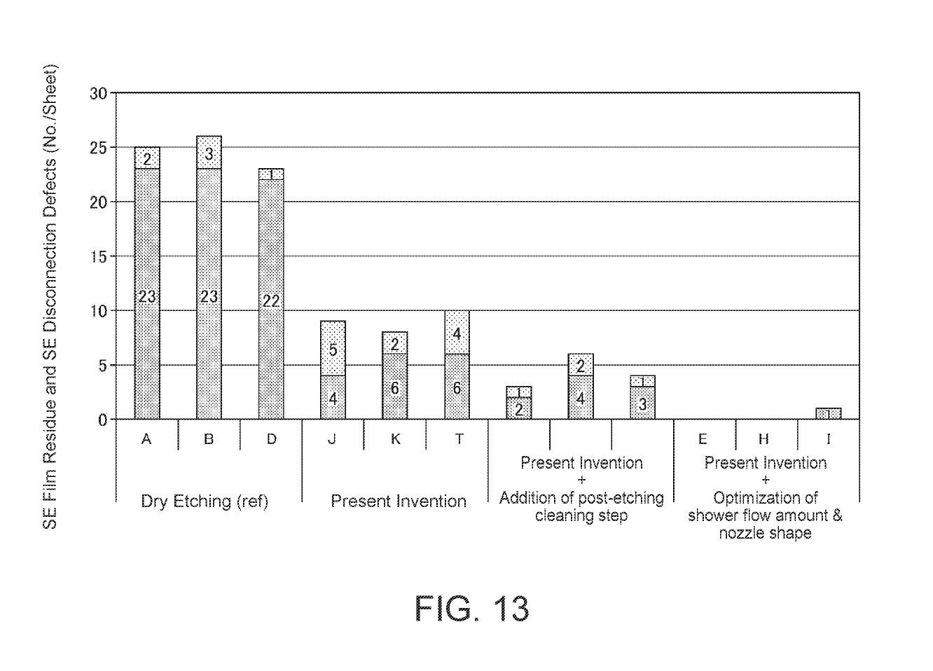

Embodiment 3 will be described with reference to FIG. 13. In Embodiment 3, cleaning parameters are set such that the cleaning solution is sprayed generally uniformly on the multilayer film in the step of cleaning the surface of the source wiring line, source electrode, and drain electrode described in Embodiment 2. Specifically, the spray flow amount of the cleaning solution during cleaning and the shape of the nozzle for spraying the cleaning solution are optimized, for example. The graph in FIG. 13 shows comparisons between the number of source electrode disconnection defects due to film residual defects and excessive etching of the source electrode caused by improper etching for a source electrode formed by a conventional method, a source electrode formed by the manufacturing method of Embodiment 1, a source electrode formed by the manufacturing method of Embodiment 2, and a source electrode formed by the manufacturing method of the present embodiment or namely a manufacturing method whereby the cleaning parameters for the step of cleaning are optimized (hereinafter, “the present method”). The horizontal axis of FIG. 13 includes the items shown on the horizontal axis of FIG. 12 and additionally three samples (E, H, I) of the configuration formed by the present method (i.e., present invention+optimization of shower flow amount and nozzle shape). Furthermore, the items shown by the vertical axis in FIGS. 11 and 12 are the same as the vertical axis in FIG. 13.

As shown by the graph in FIG. 13, using the present method reduces both the number of film residual defects of the source electrode and the number of disconnection defects of the source electrode to almost zero. Using the present method in this manner makes it possible to reduce the number of defective products caused by the source electrode to almost zero, which makes it possible to realize an even higher yield.

Modification examples of the respective embodiments mentioned above are described below.

(1) In the respective embodiments described above, an example is shown in which the source wiring line, source electrode, and drain electrode are each made of a multilayer structure constituted by a titanium first conductive film, aluminum second conductive film, and titanium third conductive film, but the material for forming the source wiring line, source electrode, and drain electrode is not limited to these. The second conductive film may use an aluminum alloy instead of aluminum, for example. Furthermore, the source wiring line, source electrode, and drain electrode are not limited to a three-layer structure.

(2) In addition to the respective embodiments described above, the etching parameters during dry etching can be modified as appropriate. The etching parameters may be set in accordance with the material to be etched.

(3) In addition to the respective embodiments described above, the etching parameters during wet etching can be modified as appropriate. The etching parameters may be set in accordance with the material to be etched.

(4) In the respective embodiments described above, an example was shown in which a method of manufacturing of the present invention was used in the manufacturing process of the source wiring line, source electrode, and drain electrode, but the method of manufacturing of the present invention may be used in the manufacturing process of the gate wiring line and gate electrode. In such a case, it is possible to realize a high yield while forming the gate wiring line and gate electrode at high precision.

(5) In the respective embodiments described above, an example is shown in which the photoresist film is formed on the surface of the multilayer film in the manufacturing process of the source wiring line, source electrode, and drain electrode, but the resist film is not limited to being a photoresist film.

The embodiments of the present invention were described above in detail, but these are only examples, and do not limit the scope as defined by the claims. The technical scope defined by the claims includes various modifications of the specific examples described above.

Description of Reference Characters

| | |
|---|---|
| 10 | liquid crystal display device |
| 11 | liquid crystal panel |
| 11A | liquid crystal layer |
| 14 | backlight device |
| 20 | color filter substrate |
| 20A, 30A | glass substrate |
| 24 | opposite electrode |
| 30 | array substrate |
| 32 | TFT |
| 32G | gate electrode |
| 32S | source electrode |
| 32D | drain electrode |
| 34 | pixel electrode |
| 36G | gate wiring line |
| 36S | source wiring line |
| CH1 | contact hole |
| CF1 | first conductive film |
| CF2 | second conductive film |
| CF3 | third conductive film |
| GI1 | gate insulating film |
| H1, H2, H3 | opening |
| P1 | photoresist film |
| PF1 | first protective film |
| PF2 | second protective film |

1. A method of manufacturing multilayer metal patterns, comprising:
a multilayer film forming step of forming a multilayer film comprising a plurality of metal films layered together;
after the multilayer film forming step, a resist forming step of forming a resist film that has openings patterned on the multilayer film;
after the resist forming step, a dry etching step of dry etching the multilayer film using the patterned resist film as a mask to remove at least one of the metal films positioned at a top of the multilayer film in areas exposed by the openings; and
after the dry etching step, a wet etching step of wet etching the multilayer film using the patterned resist film as a mask to remove at least the metal film or films of the multilayer film remaining in the areas exposed by the openings.

2. The method of manufacturing the multilayer metal patterns according to claim 1, wherein the multilayer film forming step includes forming a metal film containing titanium at a top of the multilayer film.

3. The method of manufacturing the multilayer metal patterns according to claim 1, wherein the multilayer film forming step includes forming a metal film containing titanium at a bottom of the multilayer film.

4. The method of manufacturing the multilayer metal patterns according to claim 1, wherein an etching solution containing fluorine is used in the wet etching step.

5. The method of manufacturing the multilayer metal patterns according to claim 1, further comprising, between the dry etching step and the wet etching step, a cleaning step of cleaning the metal multilayer film using a cleaning solution.

6. The method of manufacturing the multilayer metal patterns according to claim 5, wherein in the cleaning step, cleaning parameters are set such that the cleaning solution is injected generally uniformly on the multilayer film.

7. The method of manufacturing the multilayer metal patterns according to claim 1, wherein in the wet etching step, spraying parameters of an etching solution are set such that the etching solution is sprayed generally uniformly in the areas exposed by the openings in the multilayer film.

8. A method of manufacturing a semiconductor device, comprising:
a semiconductor film forming step of forming a semiconductor film; and
a multilayer metal patterns forming step of using the method of manufacturing the multilayer metal patterns according to claim 1 to form a pair of the metal multilayer patterns, said pair of the metal multilayer patterns being electrically connected via the semiconductor film.

9. A method of manufacturing a liquid crystal display device, comprising:
a first substrate forming step of using the method of manufacturing the semiconductor device according to claim 8 to form a plurality of the semiconductor devices in a matrix pattern on the first substrate;
a second substrate forming step of forming a second substrate facing the first substrate; and
a liquid crystal layer forming step of forming a liquid crystal layer containing liquid crystal molecules between the first substrate and the second substrate.
